(19) United States
(12) Patent Application Publication
(10) Pub. No.: US 2007/0031741 A1
(43) Pub. Date: Feb. 8, 2007

(54) EUVL reflection device, method of fabricating the same, and mask, projection optics system and EUVL apparatus using the EUVL reflection device

(75) Inventors: Hoon Kim, Siheung-si (KR); Suk-pil Kim, Yongin-si (KR); I-hun Song, Seongnam-si (KR); Young-soo Park, Suwon-si (KR); Seung-hyuk Chang, Seongnam-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/498,020

(22) Filed: Aug. 3, 2006

(30) Foreign Application Priority Data
Aug. 3, 2005 (KR) 10-2005-0071080

(51) Int. Cl. G02B 5/20; F21V 9/06; F21V 9/04; G21K 5/00; G03F 1/00; G02B 5/08

(52) U.S. Cl. 430/5; 378/35; 359/360; 359/361

(57) ABSTRACT

A reflection device that may include a substrate and a multi-reflection layer formed on the substrate. The multi-reflection layer may be formed of a material capable of reflecting EUV rays. The multi-reflection layer may be formed by stacking a plurality of layer groups, each including a first material layer, a surface-treated layer obtained by surface-treating the first material layer, and a second material layer formed on the surface-treated layer. A method of fabricating the reflection device that may include preparing a substrate and forming a multi-reflection layer on the substrate from a material capable of reflecting EUV rays. The forming of the multi-reflection layer may be performed by repeatedly forming a layer group. The forming of the layer group may include forming a first material layer, surface-treating the first material layer, and forming a second material layer on the surface-treated first material layer.

### PRIORITY STATEMENT

This application claims the benefit of priority to Korean Patent Application No. 10-2005-0071080, filed on Aug. 3, 2005, in the Korean Intellectual Property Office, the disclosure of which is incorporated herein in its entirety by reference.

### BACKGROUND OF THE INVENTION

1. Field of the Invention

Example embodiment of the present invention relate to a reflection device used for extreme ultraviolet lithography (EUVL) and a method of fabricating the same. More particularly, example embodiments of the present invention relate to a reflection device having a reflection layer for reflecting extreme ultraviolet (EUV) light with low internal stress, a method of fabricating the reflection device, and an EUVL mask, a projection optics system and an EUVL apparatus using the reflection device.

2. Description of the Related Art

Technology involving an exposure wavelength of EUV light referred to as soft X-rays, which is an exposure technology for implementing a lithographic resolution of 45 nm or less, has been actively researched for use in photolithography processes of a semiconductor fabrication process. In an EUV photolithographic technology, EUV light having a wavelength shorter than 100 nm, e.g., about 13.5 nm, may be used.

Since most materials absorb light in the EUV range, it is difficult and/or impossible to use refractive optical devices. Therefore, EUV exposure technology generally uses and/or requires a mask that reflects EUV light. Further, a projection optics system including a plurality of reflective mirrors is generally used and/or required to guide the EV light reflected by a mask to a wafer. The EUV light may be irradiated on the mask, which may be installed in a chamber, and the EUV light reflected by the mask may be irradiated on the wafer, thereby forming a pattern corresponding to the mask on the wafer.

A conventional reflection device (e.g., the mask and the reflective mirrors) may have a multi-reflection layer in which a plurality of heterogeneous layers (e.g., molybdenum/silicon (Mo/Si) layers) are stacked to reflect the EUV light. Generally, the multi-reflection layer is formed by ion-beam sputtering.

However, in conventional reflection devices, there generally exists an internal stress, which may induce a relatively strong compression in the multi-reflection layer in which a plurality of Mo/Si bilayers may be stacked. Accordingly, a deformation may occur that affects optical properties of the reflection devices due at least in part to the internal stress. That is, the internal stress may result in a considerable deformation of the multi-reflection layer that affects its optical properties, making it difficult to accurately fabricate a reflection device. For example, the internal stress may bend the mirror surface of the reflection device, which may cause image distortion.

The existence of an interdiffusion layer 3 at an interface between a molybdenum layer 1 and a silicon layer 5 may cause internal stress as illustrated in FIG. 1. FIG. 2 is a photograph illustrating a section of a multi-reflection layer that may be formed by alternately and repeatedly stacking a molybdenum layer 11 and a silicon layer 15 on a silicon substrate through ion-beam sputtering. Referring to FIG. 2, an interdiffusion layer 13 may be formed at an interface between the molybdenum layer 11 and the silicon layer 15. The interdiffusion layer 13 may be formed of molybdenum silicide due to interdiffusion at the interface. This interdiffusion layer 13 may cause volume contraction and strain at the interface. FIG. 1 illustrates an example where the volume contraction at the interface, which may be due to the interdiffusion, reduces the thickness of the Mo/Si bilayer. In particular, the left sectional view in FIG. 1 illustrates a desired thickness of the Mo/Si bilayer, while the right sectional view illustrates the reduced thickness of the Mo/Si layer, which may be caused by the interdiffusion.

A strain induced by a peening effect where molybdenum atoms are embedded at interstitial positions of the silicon layer during sputtering may also cause internal stress.

### SUMMARY

Example embodiments of the present invention provide a reflection device capable of reducing an internal stress in a multipe-reflection layer for reflecting an EUV light by reducing and/or preventing an interdiffusion layer from being formed in a multiple-reflection layer, a method of fabricating the reflection device, and a mask, a projection optics system and an EUVL apparatus using the reflection device.

An example embodiment of the present invention provides a reflection device. The reflection device may include a substrate; and a multi-reflection layer formed on the substrate, the multi-reflection layer being formed of a material capable of reflecting EUV rays, wherein the multi-reflection layer includes a plurality of stacked layer groups, each of the layer groups including a first material layer, a surface-treated layer obtained by surface-treating the first material layer, and a second material layer formed on the surface-treated layer.

According to an example embodiment of the present invention, the first material layer may be a silicon layer and the second material layer may be a molybdenum layer.

According to an example embodiment of the present invention, the surface-treated layer may be obtained by surface-treating the first material layer with an oxygen ion beam or an argon ion beam.

According to an example embodiment of the present invention, the first and second material layers may be formed by sputtering.

According to an example embodiment of the present invention, the substrate may be a silicon substrate or a quartz substrate.

An example embodiment of the present invention provides an EUVL mask. The EUVL mask may include a reflection device having one or more of the characteristics described above; and an absorption pattern formed on the multi-reflection layer of the reflection device.

An example embodiment of the present invention provides an EUVL projection optics system. The EUVL projection optics system may include a plurality of reflective mirrors, wherein at least one reflective mirror has a reflection device having one or more of the characteristics described above.

An example embodiment of the present invention provides a lithographic apparatus. The lithographic apparatus may irradiate a beam with pattern information of a mask onto a wafer using a projection optics system and may include the EUVL projection optics system described above.

An example embodiment of the present invention provides a method of fabricating a reflection device. The method may include preparing a substrate; and forming a multi-reflection layer on the substrate, the multi-reflection layer being formed of a material capable of reflecting EUV rays, wherein the forming of the multi-reflection layer includes repeatedly forming a layer group a desired and/or predetermined number of times, the forming of the layer group including: forming a first material layer; surface-treating the first material layer; and forming a second material layer on the first material layer which is surface-treated.

According to an example embodiment of the present invention, the first material layer may include silicon and the second material layer may include molybdenum.

According to an example embodiment of the present invention, the surface-treating of the first material layer may be performed using an oxygen ion beam or an argon ion beam.

According to an example embodiment of the present invention, the first and second material layers may be formed by sputtering.

An example embodiment of the present invention provides an EUVL mask. The EUVL mask may include a reflection device formed by the method described above; and an absorption pattern formed on the multi-reflection layer of the reflection device.

An example embodiment of the present invention provides an EUVL projection optics system. The EUVL projection optics system may include a plurality of reflective mirrors, wherein at least one of the reflective mirrors includes the reflection device formed by the method described above.

An example embodiment of the present invention provides a lithographic apparatus. The lithographic apparatus may irradiate a beam with pattern information of a mask onto a wafer by a projection optics system and may include the EUVL projection optics system having the reflection device fabricated by the method described above.

### BRIEF DESCRIPTION OF THE DRAWINGS

The above and other features and advantages of the example embodiments of the present invention will become more apparent by describing in detail example embodiments of the present invention with reference to the attached drawings in which:

FIG. 1 illustrates the existence of an interdiffusion layer at an interface between a molybdenum layer and a silicon layer in a conventional reflection device;

FIG. 2 is a photograph illustrating a section of a multi-reflection layer of a conventional reflection device formed by alternately and repeatedly stacking a silicon layer and a molybdenum layer on a silicon substrate through ion-beam sputtering;

FIG. 3 is a schematic view of a deposition system for fabricating an EUVL reflection device according to an example embodiment of the present invention;

FIGS. 4A through 4D are sectional views illustrating a method of forming a multi-reflection layer on a substrate according to an example embodiment of the present invention;

FIG. 5 illustrates an EUVL mask of a reflection device according to an example embodiment of the present invention;

FIG. 6 is an off-axis projection optics system and EUVL projection optics system using a reflection device according to an example embodiment of the present invention;

FIG. 7 is a schematic view illustrating an EUVL apparatus that may irradiate a beam with mask pattern information onto a wafer using an off-axis projection optics system according to an example embodiment of the present invention;

FIG. 8 illustrates an example analytic result obtained from example embodiments of the present invention using a transmission electron microscope;

FIG. 9 is a graph illustrating the measured X-ray reflectivity (XRR) of samples 1, 2, 3 and 4 when voltages of oxygen ion beam for the samples are different from one another but other conditions, for example, a Mo/Si layer deposition condition for ion beam sputtering and the surface treatment condition for oxygen ion beam are the same;

FIG. 10 is a graph illustrating the thicknesses of the Mo/Si bilayer for the samples 1, 2, 3 and 4 which represent the results of FIG. 9;

FIG. 11 is a graph illustrating measured internal stress for the samples 1, 2, 3 and 4 which represent the results of FIG. 9;

FIG. 12 is a graph illustrating residual stress when using an oxygen ion beam and an argon ion beam for surface-treatment according to an example embodiment of the present invention; and

FIGS. 13A and 13B illustrate detection results of oxygen at the interface of the Mo/Si bilayer from example embodiments of the present invention obtained using time-of-flight secondary ion mass spectrometry.

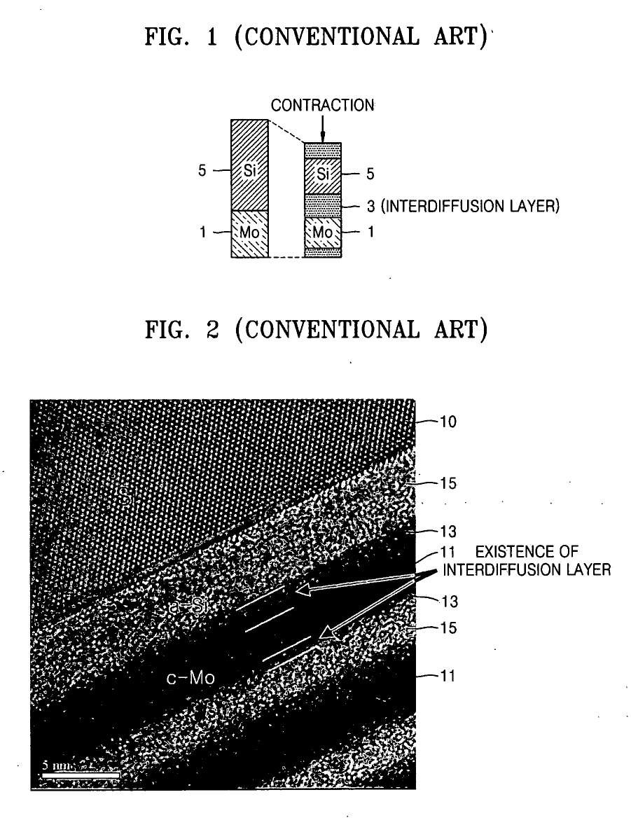

### DETAILED DESCRIPTION OF EXAMPLE EMBODIMENTS OF THE PRESENT INVENTION

Example embodiments of the present invention are described below with reference to the accompanying drawings. The present invention may, however, be embodied in many different forms and should not be construed as limited to the example embodiments described herein. Rather, the example embodiments are provided so that this disclosure will be thorough, complete and fully convey the scope of the present invention to those skilled in the art. In the drawings, the size and relative sizes of films and regions are exaggerated for clarity. The drawings are not to scale. Like reference numerals designate like components throughout the drawings.

It will also be understood that when a component, film or layer is referred to as being “on” another component, film or layer, the component, film or layer may be directly on the other component, film or layer or intervening components, films or layers may be present. As used herein, the term “and/or” may include any and all combinations of one or more of the associated listed items.

It will also be understood that, although the terms first, second, etc. may be used herein to describe various elements, components, regions and/or sections. These elements, components, regions and/or sections should not be limited by these terms. These terms may be used to distinguish one element, component, region and/or section from another element, component, region and/or section. For example, a first element, component, region and/or section discussed below could be termed a second element, component, region and/or section without departing from the teachings of the present invention.

The terminology used herein is for the purpose of describing particular example embodiments and is not intended to limit of the invention. As used herein, the singular terms “a,” “an” and “the” are intended to include the plural forms as well, unless the context clearly indicates otherwise. It will be further understood that the terms “includes” and/or “including”, when used in this specification, specify the presence of stated features, integers, steps, operations, elements, components and/or groups thereof, but do not preclude the presence and/or addition of one or more other features, integers, steps, operations, elements, components, and/or groups thereof.

Unless otherwise defined, all terms (including technical and scientific terms) used herein may have the same meaning as what is commonly understood by one of ordinary skill in the art. It will be further understood that terms, such as those defined in commonly used dictionaries, should be interpreted as having a meaning that is consistent with their meaning in the context of the relevant art and will not be interpreted in an idealized and/or overly formal sense unless expressly so defined herein.

Example embodiments of the present invention will now be described more fully with reference to the accompanying drawings, in which example embodiments of the present invention are shown.

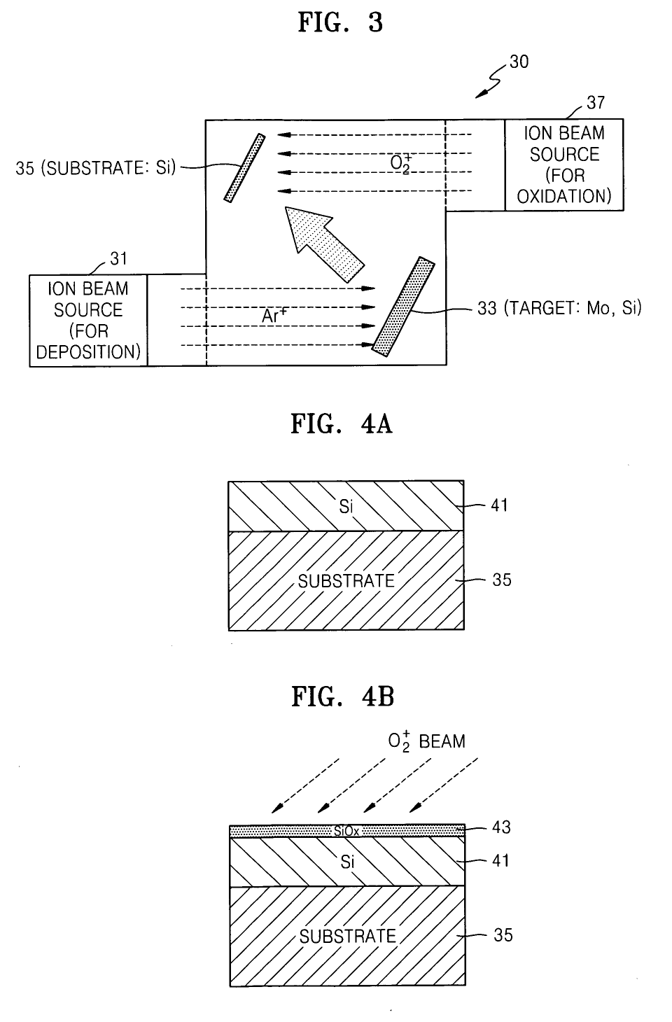

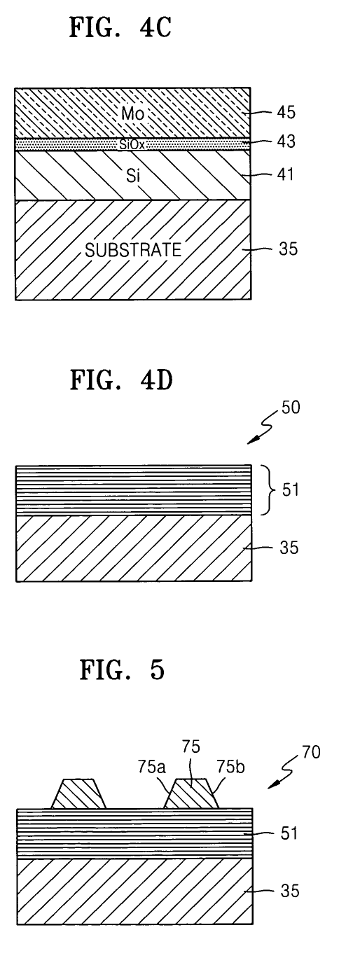

FIG. 3 is a schematic view of a deposition system 30 for fabricating an EUVL reflection device according to an example embodiment of the present invention. FIGS. 4A through 4D are cross sectional views illustrating a method of forming a multi-reflection layer on a substrate according to an example embodiment of the present invention using the deposition system 30 of FIG. 3, for example.

Referring to FIG. 3, the deposition system 30 may supply an argon ion (Ar⁺) beam from an ion beam source 31 to a target 33. Target materials sputtered by the argon ion beam from the target 33 may be deposited on a silicon substrate 35, for example.

If depositing a molybdenum layer on the substrate 35, the target 33 is a molybdenum target. If depositing a silicon layer on the substrate 35, the target 33 is a silicon target. In order to alternately deposit the molybdenum and silicon layers on the substrate 35, the molybdenum target and the silicon target which may be arranged in the same plane in the deposition system 30 may be alternately disposed along a path of the deposition ion beam. In this case, the silicon layer and the molybdenum layer may be alternately deposited to form a multi-reflection layer in one chamber.

Referring to FIGS. 3, 4A and 4B, if the target 33 is the silicon target, the deposition ion beam may be irradiated on the silicon target after positioning the silicon target at a desired and/or defined location, and silicon separated from the silicon target by the sputtering may be deposited on the substrate 35 so that a silicon layer 41 is formed, as illustrated in FIG. 4A. After forming the silicon layer 41, a surface treatment may be performed on the silicon layer 41 by irradiating an oxidation ion beam, e.g., an oxygen ion (0₂⁺) beam into the silicon layer 41. As a result, a surface-treated layer, e.g., a silicon oxide (SiOx) layer 43 may be formed on the silicon layer 41.

FIG. 4A illustrates a state where the silicon layer 41 is formed on the substrate 35. FIG. 4B illustrates a state where the silicon oxide (SiOx) layer 43 is formed on the silicon layer 41 by a surface-treatment performed with an oxygen ion beam according to an example embodiment of the present invention.

After a surface-treatment with the oxygen ion beam, the deposition ion beam may be irradiated on the molybdenum target after the molybdenum target is positioned at a desired and/or preset location, and molybdenum separated from the molybdenum target by the sputtering may be deposited on the silicon oxide layer 43 so that a molybdenum layer 45 may be formed, as illustrated in FIG. 4C.

The processes of forming the silicon layer 41 on the molybdenum layer 45 by sputtering, surface-treating the silicon layer 41 with the oxygen ion beam, and forming the molybdenum layer 45 by sputtering may be repeatedly performed. For example, the processes may be repeated several times according to an example embodiment of the present invention.

Through the repeated operations, a plurality of molybdenum/silicon bilayers may be stacked to form a multi-reflection layer 51. FIG. 4D illustrates the reflection device 50 having the multi-reflection layer 51 according to an example embodiment of the present invention.

In the reflection device 50 according to an example embodiment of the present invention, a material containing silicon may be used as the substrate 35. For example, the substrate 35 may be a silicon substrate or a quartz (SiO₂) substrate. Through a deposition such as sputtering, for example, the silicon layer 41 may be formed as amorphous silicon (a-Si) and the molybdenum layer 45 may be formed as crystalline or polycrystalline molybdenum (c-Mo).

The silicon oxide layer 43 formed on the silicon layer 41 by surface-treating the silicon layer 41 with the oxygen ion beam may inhibit molybdenum atoms from bonding with silicon atoms through interdiffusion at the interface between the molybdenum layer 45 and the silicon layer 41 during the formation of the molybdenum layer 45. As a result, the formation of an interdiffusion layer and/or a peening effect where molybdenum atoms are inserted in interstitial positions of the silicon layer may be inhibited according to example embodiments of the present invention.

In the reflection device 50 according to an example embodiment of the present invention, an uppermost layer of the reflection layer 51 may be either a molybdenum layer or a silicon layer. Further, according to an example embodiment of the present invention, the uppermost layer may be a silicon layer because the stability of a natural oxide formed on the silicon layer is excellent. The silicon oxide layer may be formed on the uppermost silicon layer using a surface treatment with the oxygen ion beam according to an example embodiment of the present invention. To obtain a desired reflectivity, the molybdenum layers and the silicon layers may be a few nanometers thick and tens of bilayers may be stacked.

FIG. 5 illustrates an EUVL mask 70 according to an example embodiment of the present invention including the reflection device 50 according to an example embodiment of the present invention. As shown in FIG. 5, the EUVL mask 70 may include the substrate 35, the multi-reflection layer 51 formed on the substrate 35, and an absorption pattern 75 formed on the reflection layer 51. The EUVL mask 70 in FIG. 5 may be include the reflection device 50 of FIG. 4D and the absorption pattern 75. The EUVL mask 70 may further include a capping layer (not shown) on the reflection layer 51 to protect the reflection layer 51 when forming the absorption pattern 75 on the reflection layer 51. In addition, the EUVL mask 70 may include a buffer layer (not shown) between the absorption pattern 75 and the reflection layer 51 or the capping layer.

The absorption pattern 75 may be formed to have a region absorbing EUV light and a window through which the EUV light transmits. In an example embodiment of the present invention, the absorption pattern 75 may be formed of a material capable of absorbing EUV light, e.g., a material incorporating a metal. For example, the absorption pattern 75 may be formed of a tantalum nitride (TaN) layer or the like and may be formed to have an absorption region for absorbing the EUV light. The absorption pattern 75 may be formed of tantalum nitride, tantalum (Ta), chromium (Cr), titanium nitride (TiN), titanium (Ti), aluminum-copper (Al—Cu) alloy, nickel silicide (NiSi), tantalum silicon nitride (TaSiN), aluminum, etc.

The absorption pattern 75 may be modified into various shapes according to an example embodiment of the present invention. That is, the slopes of sidewalls 75a and 75b of the absorption pattern 75 may be modified.

FIG. 5 illustrates that the sidewalls 75a and 75b of the absorption pattern 75 adjacent to the window may be inclined with respect to the reflection layer 51. The angles of inclination of the sidewalls 75a and 75b of the absorption pattern 75 may be substantially equal to an incident angle of the EUV light. In this case, when the EUVL mask 70 is photo-exposed with an EUV ray, the dimensions of the absorption pattern 70 are substantially equal to actual dimensions of a pattern formed on a silicon wafer.

In another example embodiment of the present invention, some of the sidewalls of the absorption pattern 75 may be substantially vertical, while others may be inclined. For example, the sidewalls of the absorption pattern that are perpendicular to an incident plane of the EUV rays may be inclined, and the sidewalls of the absorption pattern that are parallel to the incident plane of the EUV ray may be vertical. The incident plane of the EUV ray is defined as the plane formed by the EUV ray incident on the reflection layer 51 and a normal line perpendicular to the reflection layer 51.

The EUVL mask 70 having an absorption pattern 75 is disclosed in U.S. patent application Ser. No.11/274,474, filed on Nov. 16, 2005, the entire contents of which are hereby incorporated by reference in their entirety. Therefore, a detail description of the EUVL mask 70 will be omitted for conciseness.

A projection optics system including a plurality of reflective mirrors for propagating the EUV light reflected by an EUVL mask toward a wafer may be used in semiconductor manufacturing. The reflection device 50 may be used as the reflective mirror in a projection optics system according to an example embodiment of the present invention. That is, the EUVL projection optics system may use the reflection device 50 as at least one of a plurality of reflective mirrors.

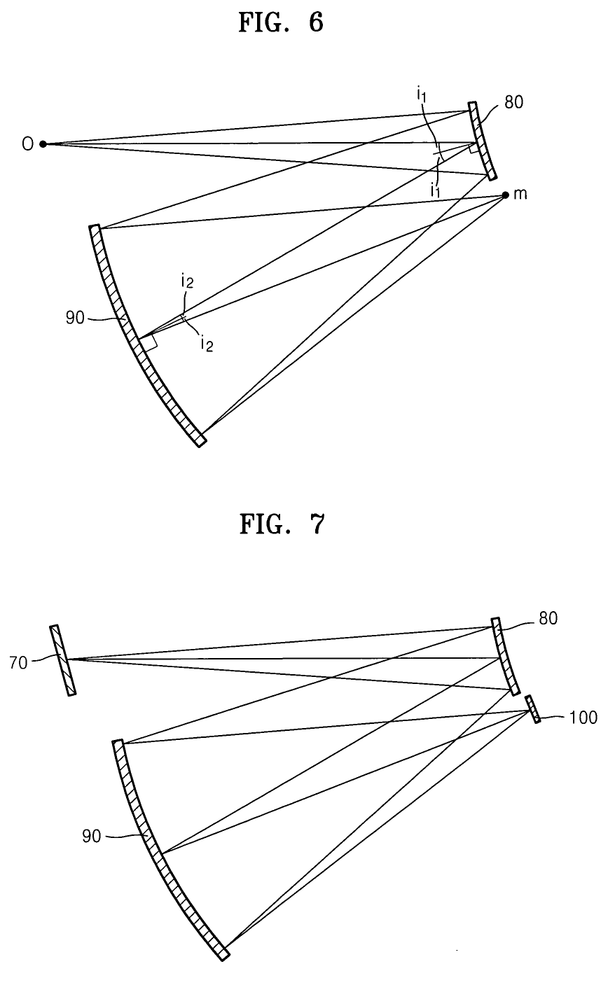

FIG. 6 is an off-axis projection optics system, which may be used as an EUVL projection optics system and may include the reflection device 50 according to an example embodiment of the present invention. The projection optics system of FIG. 6 is disclosed in U.S. patent application Ser. No. 11/453,775, filed on Jun. 16, 2006, which claims priority to corresponding Korean Patent Application No. 2005-52727, filed on Jun. 18, 2005, the entire contents of both of which are hereby incorporated by reference in their entirety.

Referring to FIG. 6, the off-axis projection optics system may include a first mirror 80 and a second mirror 90 for guiding incident light to an image plane. The first and second mirrors 80 and 90 have an off-axis arrangement relationship with each other. The off-axis projection optics system may include at least one pair of the first and second mirrors 80 and 90. The first mirror 80 may be a convex mirror and the second mirror 90 may be a concave mirror. In addition, the first and second mirrors 80 and 90 may be aspheric mirrors. Furthermore, the first and second mirrors 80 and 90 may be formed in bilateral symmetric shapes with respect to the central points (apex points) of the mirrors.

The first and second mirrors 80 and 90 may be designed such that they satisfy equation 1 below. A tangential radius of curvature and a sagittal radius of curvature of the first mirror 80 are denoted as R₁ₜ and R₁ₛ, respectively, and a tangential radius of curvature and a sagittal radius of curvature of the second mirror 90 are denoted as R₂ₜ and R₂ₛ, respectively. In addition, an incidence angle of the ray incident on the first mirror 80 from an object point O is denoted as i₁ and an incidence angle of the ray incident on the second mirror 90 after being reflected from the first mirror 80 is denoted as i₂.
R₁ₜ cosi₁=R₂ₜ cosi₂
R₁ₛ=R₁ₜ cos²i₁
R₂ₛ=R₂ₜ cos²i₂ (1)

If the first and second mirrors 80 and 90 satisfy Equation 1, it is possible to reduce and/or minimize third order aberration, which is a general Seidel aberration, for example, a coma, astigmatism, spherical aberration, field curvature, etc.

The reflection device 50 may be used as one of the first and second mirrors 80 and 90 according to an example embodiment of the present invention. In this case, when forming the multi-reflection layer 51, the shape of the substrate may be formed to correspond to a curvature of the first or second mirrors 80 and 90.

The EUVL projection optics system using the reflection device 50 according to an example embodiment of the present invention is not limited to the example embodiment illustrated in FIG. 6. That is, various modifications can be made to the EUVL projection optics system as long as at least one reflective mirror is a reflective device according to an example embodiment of the present invention.

FIG. 7 is a schematic view illustrating the EUVL apparatus that may irradiate a beam with mask pattern information onto a wafer using the off-axis projection optics system in FIG. 6, for example. FIG. 7 illustrates an example embodiment in which the mask 70 in FIG. 5 may be used.

Referring to FIGS. 5 through 7, the patterned reflection mask 70 may be positioned on an object plane and a wafer 100 may be positioned on an image plane. The EUV beam irradiated on the mask 70 may be incident on the first mirror 80 after being reflected from the mask 70. The EUV beam may be reflected from the first mirror 80 and may be incident on the second mirror 90. The incident EUV beam may be reflected by the second mirror 90 and focused on the wafer 100 located on the image plane so that a desired and/or predetermined pattern corresponding to the absorption pattern of the mask 70 may be formed on the wafer.

According to an example embodiment of the present invention, the number of mirrors used for the projection optics system is at least two. In addition to the at least two mirrors, it is possible to use at least one additional mirror in consideration of an installation location and/or direction of the mask and the wafer used and/or required for the EUVL apparatus.

Various example measurement results are shown below to illustrate that the interdiffusion of the molybdenum atoms may be inhibited if the surface-treatment is performed to a silicon layer using a desired and/or predetermined ion beam according to an example embodiment of the present invention.

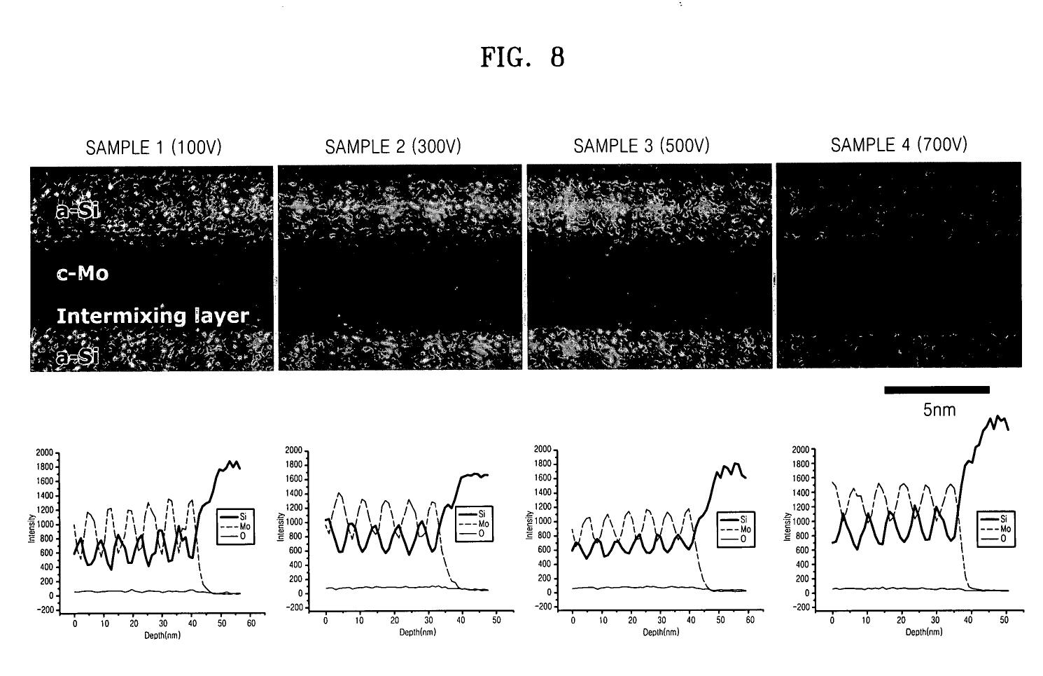

FIG. 8 illustrates analysis results from an example embodiment of the present invention obtained with a transmission electron microscope (TEM).

In FIG. 8, the upper four TEM photographs illustrate the thickness variation of an intermixing layer of silicon and molybdenum, i.e., an interdiffusion layer, where a voltage of the oxygen ion beam is set to 100 V, 300 V, 500 V and 700 V, respectively. Here, a sample 1, a sample 2, a sample 3 and a sample 4 are measured at 100 V, 300 V, 500 V and 700 V, respectively.

The lower four graphs of FIG. 8 illustrate depth profiles, i.e., line scans, for the samples. In particular, the lower four graphs of FIG. 8 illustrate the existing amount of silicon, molybdenum and oxygen of each sample according to depth.

The TEM photographs of the samples show that the thickness of the intermixing layer of silicon and molybdenum, i.e., the interdiffusion layer, decreases as the voltage of the oxygen ion beam is increased. In addition, the graphs of the depth profiles show that a region where silicon and molybdenum overlap decreases as the voltage of the oxygen ion beam is increased. This is because the surface-treatment with the oxygen ion beam may inhibit the interdiffusion of the molybdenum atoms. Therefore, as the voltage of the oxygen ion beam is increased, the surface-treatment may be performed more effectively, and thus the interdiffusion of the molybdenum atoms may be more effectively inhibited.

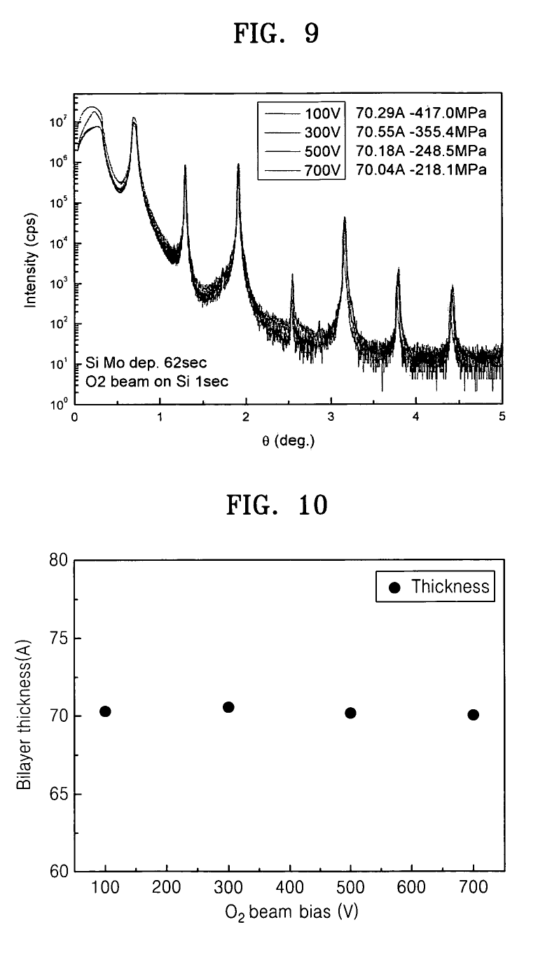

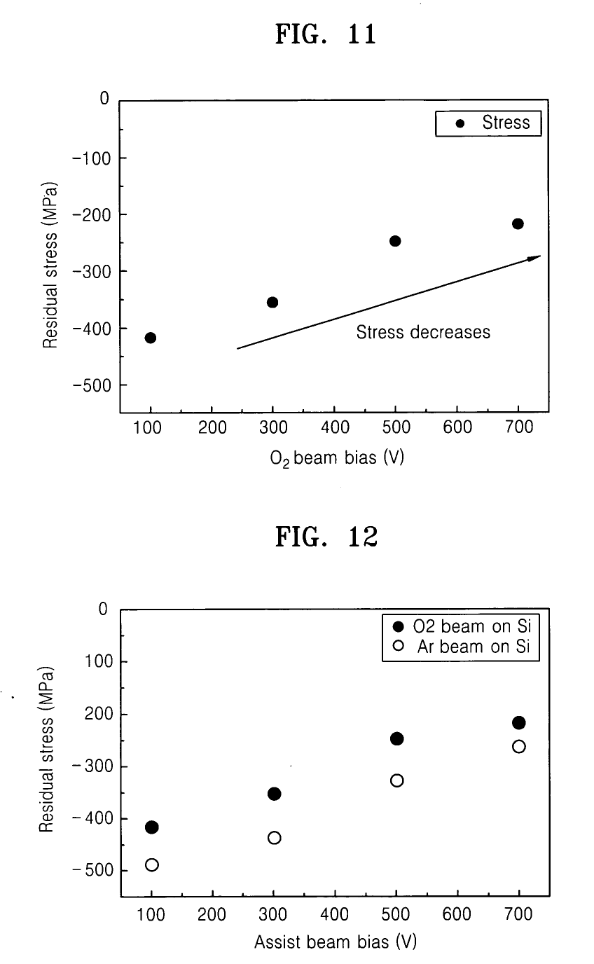

FIG. 9 is a graph illustrating the measured X-ray reflectivity (XRR) of samples 1, 2, 3 and 4 when voltages of the ion beams for the samples are different from one another, but other conditions, for example, a Mo/Si layer deposition condition for the ion beam sputtering and the surface treatment condition for the oxygen ion beam, are the same. FIG. 10 is a graph illustrating the thicknesses of the Mo/Si bilayer for the samples 1, 2, 3 and 4 which represent the results illustrated in FIG. 9. FIG. 11 is a graph illustrating measured internal stresses for the samples 1, 2, 3 and 4 which represent the results as illustrated in FIG. 9.

The samples 1, 2, 3 and 4 used for obtaining the results of FIGS. 9 through 11 were surface-treated using an oxygen ion beam for about 1 second under voltages of 100 V, 300 V, 500 V and 700 V, respectively. In addition, the Mo/Si bilayers of the samples 1, 2, 3 and 4 were formed by sputtering for 62 seconds and performing the oxygen ion beam treatment for about 1 second on the silicon layer.

Referring to FIG. 9, the positions of the reflectivity peaks for the samples 1, 2, 3 and 4 are almost identical to one another. These measurement results illustrate that the thickness variation of the Mo/Si bilayer may be insignificant regardless of the voltage used for the oxygen ion beam treatment, i.e., an oxygen ion beam bias value.

Referring to FIG. 10, the Mo/Si bilayer thicknesses of the samples 1, 2, 3 and 4 are 70.29 Å, 70.55 Å, 70.18 Å, and 70.04 Å, respectively. In FIG. 10, the abscissa axis represents the oxygen ion beam bias voltage in volts, and the ordinate axis represents the thickness of the bilayer in angstroms. Based on the results shown in FIG. 10, after the silicon surface was surface-treated with the oxygen ion beam for about 1 second during the deposition of the Mo/Si layer, the thickness variation by the surface treatment was insignificant although the oxygen ion beam voltage was set to 100 V, 300 V, 500 V and 700 V, respectively.

Referring to FIG. 11, the residual stress in the multilayer was decreased as the oxygen ion beam bias voltage was increased.

From the results shown FIGS. 10 and 11 obtained from example embodiments of the present invention, it should be understood that the thickness of the bilayer is relatively unchanged by an increase in the oxygen ion beam bias, whereas the residual stress is decreased.

Further, it was verified that, when the oxygen ion beam treatment is not performed, the residual stress is about −510 MPa, but when the oxygen ion beam treatment is performed using an oxygen ion beam bias voltage of 700V, the residual stress is decreased to about −218 MPa.

Although an oxygen ion beam may be used for the surface-treatment for the silicon layer as described above, other kinds of ion beams may also be used for the surface treatment of the silicon layer according to an example embodiment of the present invention.

FIG. 12 is a graph illustrating the residual stress when an oxygen ion beam is used for the surface treatment and the residual stress when an argon ion beam is used for the surface-treatment.

As shown in FIG. 12, when the argon ion beam is used for the surface-treatment, the residual stress may be lower than the case where the surface treatment is not performed. For example, the residual stress is lower than −510 MPa in the case where the argon ion beam is used for the surface-treatment. In addition, as the argon ion beam bias is increased, the residual stress decreases.

Furthermore, it should be understood from FIG. 12 that the internal stress obtained using the oxygen ion beam for the surface-treatment is about 10% less than the internal stress obtained using the argon ion beam for the surface-treatment.

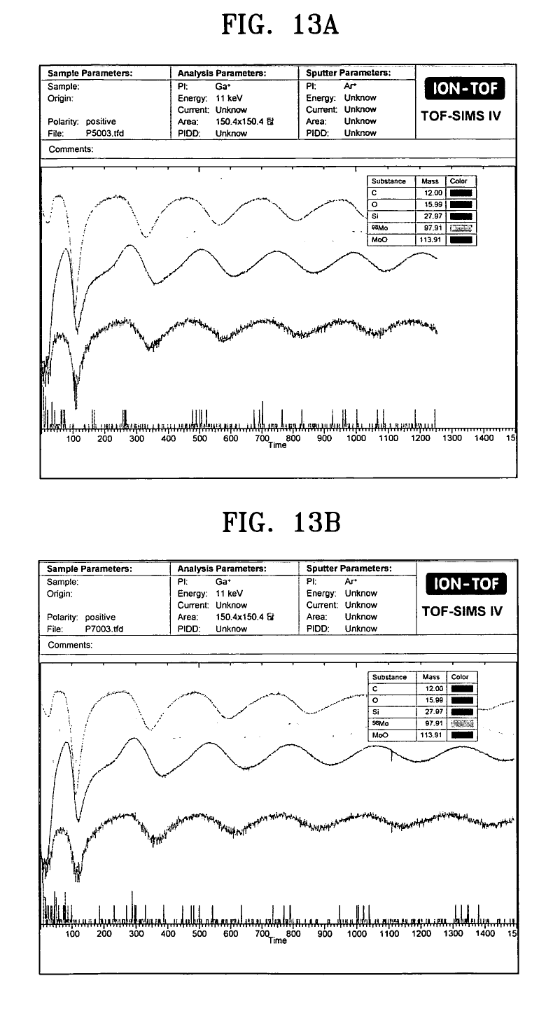

FIGS. 13A and 13B illustrate detection results of oxygen at the interface of the Mo/Si bilayer obtained using a time-of-flight secondary ion mass spectrometry (TOF-SIMS). FIG. 13A was obtained from a sample that was surface-treated with an oxygen ion beam under an ion beam bias voltage of 500 V, and FIG. 13B was obtained from a sample that was surface-treated with an oxygen ion bean under an ion beam bias voltage of 700 V.

Since the detection peak period of silicon and the detection peak period of oxygen were repeated identically, it should be understood that the oxygen was detected only at the interface of the Mo/Si bilayer. Thus, it should be understood that a silicon oxide (SiOx) layer exists at the interface of the Mo/Si bilayer according to an example embodiment of the present invention.

As described above with respect to example embodiments of the present invention, when forming the reflection layer of multi-layer structure by stacking a plurality of Mo/Si bilayers to reflect the EUV ray, it is possible to relieve the internal stress in the multi-layer structure by surface-treating the silicon layer after forming the silicon layer.

According to example embodiments of the present invention as described above, it is possible to implement the EUVL reflection device in which the internal stress is released by inhibiting the formation of the interdiffusion layer in the multi-reflection layer reflecting the EUV ray. Additionally, it is possible to reduce and/or minimize distortion and an error in the pattern when a photolithographic process is performed using a reflection device according to example embodiments of the present invention in which the internal stress may be reduced and/or relieved.

While the present invention has been described with reference to example embodiments thereof, it will be understood by those of ordinary skill in the art that various changes in form and details may be made therein without departing from the spirit and scope of the present invention as defined by the following claims.

What is claimed is:

1. A reflection device comprising:
a substrate; and
a multi-reflection layer formed on the substrate, the multi-reflection layer being formed of a material reflecting extreme ultraviolet (EUV) rays,
wherein the multi-reflection layer includes a plurality of stacked layer groups, each of the layer groups including a first material layer, a surface-treated layer obtained by surface-treating the first material layer, and a second material layer formed on the surface-treated layer.

2. The reflection device of claim 1, wherein the first material layer is a silicon layer and the second material layer is a molybdenum layer.

3. The reflection device of claim 2, wherein the surface-treated layer is obtained by surface-treating the first material layer with one of an oxygen ion beam and an argon ion beam.

4. The reflection device of claim 3, wherein the first and second material layers are formed by sputtering.

5. The reflection device of claim 1, wherein the surface-treated layer is obtained by surface-treating the first material layer with one of an oxygen ion beam and an argon ion beam.

6. The reflection device of claim 1, wherein the substrate is one of a silicon substrate and a quartz substrate.

7. An extreme ultraviolet lithographic (EUVL) mask comprising:
the reflection device of claim 1; and
an absorption pattern formed on the multi-reflection layer of the reflection device.

8. The EUVL mask of claim 7, wherein the first material layer is a silicon layer and the second material layer is a molybdenum layer.

9. The EUVL mask of claim 8, wherein the first and second material layers are formed by sputtering.

10. The EUVL mask of claim 7, wherein the surface-treated layer is obtained by surface-treating the first material layer with one of an oxygen ion beam and an argon ion beam.

11. The EUVL mask of claim 7, wherein the substrate is one of a silicon substrate and a quartz substrate.

12. An extreme ultraviolet lithographic (EUVL) projection optics system comprising:
a plurality of reflective mirrors,
wherein at least one of the plurality of reflective mirrors is the reflection device of claim 1.

13. The EUVL projection optics system of claim 12, wherein the first material layer is a silicon layer and the second material layer is a molybdenum layer.

14. The EUVL projection optics system of claim 13, wherein the first and second material layers are formed by sputtering.

15. The EUVL projection optics system of claim 12, wherein the surface-treated layer is obtained by surface-treating the first material layer with one of an oxygen ion beam and an argon ion beam.

16. A lithographic apparatus comprising:
the EUVL projection optics system of claim 12 irradiating a beam with pattern information of a mask onto a wafer.

17. The lithographic apparatus of claim 16, wherein the first material layer is a silicon layer and the second material layer is a molybdenum layer.

18. The lithographic apparatus of claim 17, wherein the first and second material layers are formed by sputtering.

19. The lithographic apparatus of claim 16, wherein the surface-treated layer is obtained by surface-treating the first material layer with one of an oxygen ion beam and an argon ion beam.

20. A method of fabricating a reflection device, comprising:
preparing a substrate; and
forming a multi-reflection layer on the substrate, the multi-reflection layer being formed of a material configured to reflect extreme ultraviolet (EUV) rays,
wherein the forming of the multi-reflection layer includes repeatedly forming a layer group, the forming of the layer group including:
forming a first material layer;
surface-treating the first material layer; and
forming a second material layer on the surface-treated first material layer.

21. The method of claim 20, wherein the first material layer includes silicon and the second material layer includes molybdenum.

22. The method of claim 21, wherein the surface-treating of the first material layer is performed using one of an oxygen ion beam and an argon ion beam.

23. The method of claim 22, wherein the first and second material layers are formed by sputtering.

24. The method of claim 20, wherein the surface-treating of the first material layer is performed using one of an oxygen ion beam and an argon ion beam.

25. The method of claim 20, wherein the substrate is one of a silicon substrate and a quartz substrate.

26. An EUVL mask comprising:
the reflection device formed according to the method of claim 20; and
an absorption pattern formed on the multi-reflection layer of the reflection device.

27. The EUVL mask of claim 26, wherein the first material layer includes silicon and the second material layer includes molybdenum.

28. The EUVL mask of claim 27, wherein the first and second material layers are formed by sputtering.

29. The EUVL mask of claim 26, wherein the surface-treating of the first material layer is performed using one of an oxygen ion beam and an argon ion beam.

30. The EUVL mask of claim 26, wherein the substrate is one of a silicon substrate and a quartz substrate.

31. An EUVL projection optics system comprising:
a plurality of reflective mirrors,
wherein at least one of the reflective mirrors is the reflection device formed according to the method of claim 20.

32. The EUVL projection optics system of claim 31, wherein the first material layer includes silicon and the second material layer includes molybdenum.

33. The EUVL projection optics system of claim 32, wherein the first and second material layers are formed by sputtering.

34. The EUVL projection optics system of claim 31, wherein the surface-treating of the first material layer is performed using one of an oxygen ion beam and an argon ion beam.

35. The EUVL projection optics system of claim 31, wherein the substrate is one of a silicon substrate and a quartz substrate.

36. A lithographic apparatus, comprising:
the EUVL projection optics system of claim 31 irradiating a beam with pattern information of a mask onto a wafer.

37. The lithographic apparatus of claim 36, wherein the first material layer includes silicon and the second material layer includes molybdenum.

38. The lithographic apparatus of claim 37, wherein the first and second material layers are formed by sputtering.

39. The lithographic apparatus of claim 36, wherein the surface-treating of the first material layer is performed using one of an oxygen ion beam and an argon ion beam.

40. The lithographic apparatus of claim 36, wherein the substrate is one of a silicon substrate and a quartz substrate.
